(19) United States
(12) Patent Application Publication
(10) Pub. No.: US 2016/0056800 A1
(43) Pub. Date: Feb. 25, 2016

(54) SEMICONDUCTOR DEVICE HAVING DRIVER STRUCTURE FOR REDUCING CIRCUIT AREA

(71) Applicant: Samsung Electronics Co., Ltd., Suwon-Si (KR)

(72) Inventors: Yong-Hun KIM, Seoul (KR); Jae-Bum LEE, Gwangmyeong-si (KR); Eun-Bi KO, Seosan-si (KR); Soo-Jin PARK, Suwon-si (KR); Eun-Jong JANG, Osan-si (KR)

(21) Appl. No.: 14/608,361

(22) Filed: Jan. 29, 2015

(30) Foreign Application Priority Data
Aug. 25, 2014 (KR) 10-2014-0110972

(51) Int. Cl. H03K 3/037

(52) U.S. Cl. CPC H03K 3/037

(57) ABSTRACT

The semiconductor device comprises a controller; an X-axis driver; a Y-axis driver; and an output controller receiving the X-axis and Y-axis output signals and generating driving signals.

### CROSS-REFERENCE TO RELATED APPLICATIONS

This application is based on and claims priority from Korean Patent Application No. 10-2014-0110972, filed on Aug. 25, 2014 in the Korean Intellectual Property Office, the disclosure of which is incorporated herein in its entirety by reference.

### BACKGROUND

1. Field

At least one example embodiment of the present inventive concepts relates to a semiconductor device having a driver structure for reducing a circuit area.

2. Description of the Prior Art

Schemes for reducing or minimizing a bezel of a COG (Chip On Glass) have been studied from various viewpoints. Accordingly, there has been a need for schemes to reduce an area of a gate integrated circuit, that is, a gate driving circuit, which drives respective pixels of a display panel.

### SUMMARY

One subject to be solved by the present inventive concepts is to provide a semiconductor device having a driver structure for reducing a circuit area.

Additional advantages, subjects, and features of the inventive concepts will be set forth in part in the description which follows and in part will become apparent to those having ordinary skill in the art upon examination of the following or may be learned from practice of the inventive concepts.

In one aspect of at least one example embodiment of the present inventive concepts, there is provided a semiconductor device comprising: a controller generating a control signal;

an X-axis driver receiving the control signal and generating an X-axis output signal that includes first to fourth sub X-axis output signals, the X-axis driver including first and second sub X-axis drivers that are different from each other; a Y-axis driver receiving the control signal and generating a Y-axis output signal that includes first and second sub Y-axis output signals, the Y-axis driver including first and second sub Y-axis drivers that are different from each other; and an output controller receiving the X-axis and Y-axis output signals and generating driving signals, the output controller including first to fourth sub-output controllers that are different from each other, wherein the first sub X-axis driver generates and provides the first and second sub X-axis output signals to any two of the first to fourth sub-output controllers, and the second sub X-axis driver generates and provides the third and fourth sub X-axis output signals to the other two of the first to fourth sub-output controllers, and wherein the first sub Y-axis driver generates and provides the first sub Y-axis output signal to any two of the first to fourth sub-output controllers, and the second sub Y-axis driver generates and provides the second sub Y-axis output signal to the other two of the first to fourth sub-output controllers.

In at least one example embodiment, the control signal includes a start pulse signal and a clock signal.

In at least one example embodiment, the controller comprises: a first sub-controller providing the start pulse signal to the X-axis driver and the Y-axis driver; and a second sub-controller providing the clock signal to the X-axis driver and the Y-axis driver.

In at least one example embodiment, the controller generates the control signal on the basis of a specific signal provided from an outside, and the specific signal includes information related to the start pulse signal and the clock signal.

In at least one example embodiment, the first sub X-axis driver comprises first X-axis shift register and the second sub X-axis drivers comprises second X-axis shift register, wherein the first X-axis shift register shifts bit streams that determine the X-axis output signals to the second X-axis shift register on the basis of the control signal.

In at least one example embodiment, the first sub X-axis driver further comprises: an X-axis output logic generating an X-axis output logic signal that determines a state of the first and second sub X-axis output signals on the basis of an output of the first X-axis shift register; and an X-axis level shifter generating the first and second sub X-axis output signals through boosting of a voltage of the X-axis output logic signal.

In at least one example embodiment, the X-axis level shifter provides sequentially the first and second sub X-axis output signals to any two of the first to fourth sub output controllers on the basis of the control signal.

In at least one example embodiment, the first and second X-axis shift registers are linear registers.

In at least one example embodiment, the X-axis driver further includes third and fourth sub X-axis drivers, and the first to fourth sub X-axis drivers respectively include first to fourth X-axis shifter registers.

In at least one example embodiment, the control signal includes first and second clock signals having phases that are opposite to each other.

In at least one example embodiment, the first clock signal is provided to the first and third X-axis shift registers, and the second clock signal is provided to the second and fourth X-axis shift registers.

In at least one example embodiment, the first and second sub Y-axis drivers respectively comprise first and second Y-axis shifter registers, and the first Y-axis shift register shifts bit streams that determines the Y-axis output signal to the second Y-axis shift register on the basis of the control signal.

In at least one example embodiment, the first sub Y-axis driver comprises: a Y-axis output logic generating a Y-axis output logic signal that determines a state of the first and second sub Y-axis output signals on the basis of an output of the first Y-axis shift register; and a Y-axis level shifter generating the first and second sub Y-axis output signals through boosting of a voltage of the Y-axis output logic signal.

In at least one example embodiment, the first and second Y-axis shift register are circulating registers.

In at least one example embodiment, the first sub-output controller comprises: a switch receiving an X-axis output signal and a Y-axis output signal; and an output buffer receiving an output of the switch and generating a driving signal.

In at least one example embodiment, the first sub-output controller performs any one of AND, OR, NOR, and NAND operations.

In at least one example embodiment, the first to fourth sub X-axis output signals do not overlap each other, and the first and second sub Y-axis output signals do not overlap each other.

In at least one example embodiment, the semiconductor device further comprises a delay prevention buffer arranged between the Y-axis driver and the output controller to prevent delay of the Y-axis output signal.

In another aspect of at least one example embodiment of the present inventive concepts, there is provided a semiconductor device comprising a controller generating a control signal; an X-axis driver receiving the control signal and generating an X-axis output signal that includes first to fourth sub X-axis output signals, the X-axis driver including first and second sub X-axis drivers that are different from each other; a first Y-axis driver receiving the control signal and generating a first Y-axis output signal that includes first and second sub Y-axis output signals, the first Y-axis driver including first and second sub Y-axis drivers that are different from each other; a second Y-axis driver receiving the control signal and generating a second Y-axis output signal that includes third and fourth sub Y-axis output signals, the second Y-axis driver including third and fourth sub Y-axis drivers that are different from each other; and an output controller receiving the X-axis and the first and second Y-axis output signals and generating driving signals, the output controller including first to fourth sub-output controllers that are different from each other, wherein the first sub X-axis driver generates and provides the first and second sub X-axis output signals to any two of the first to fourth sub-output controllers, and the second sub X-axis driver generates and provides the third and fourth sub X-axis output signals to the other two of the first to fourth sub-output controllers, and wherein the first and second sub Y-axis drivers generate and provide the first and second sub Y-axis output signals to the two sub-output controllers to which the first and third sub X-axis output signals are provided, and the third and fourth sub Y-axis drivers generate and provide the third and fourth sub Y-axis output signals to the other two sub-output controllers to which the second and fourth sub X-axis output signal is provided.

In still another aspect of at least one example embodiment of the present inventive concepts, there is provided a semiconductor device comprising a controller generating a start pulse signal and a clock signal; a driver receiving the start pulse signal and the clock signal and generating output signals; and an output controller receiving the output signals and generating driving signals, wherein the driver includes a plurality of X-axis drivers and a plurality of Y-axis drivers, each of the plurality of Y-axis drivers interlocks with at least two of the plurality of X-axis drivers, each of the plurality of X-axis drivers generates at least two X-axis output signals, and the output controller generates the driving signals on the basis of Y-axis output signals generated by the plurality of Y-axis drivers and X-axis output signals generated by the plurality of X-axis drivers.

### BRIEF DESCRIPTION OF THE DRAWINGS

The above and other objects, features and advantages of the present inventive concepts will be more apparent from the following detailed description taken in conjunction with the accompanying drawings, in which:

FIG. 1 is a block diagram explaining a semiconductor device according to at least one example embodiment of the present inventive concepts;

FIG. 2 is a block diagram explaining another example of a portion A of FIG. 1;

FIGS. 3 and 4 are timing diagrams explaining FIG. 2;

FIG. 5 is a diagram explaining a portion B of FIG. 1;

FIG. 6 is a timing diagram explaining the semiconductor device of FIG. 1;

FIG. 7 is a diagram explaining a portion C of FIG. 6;

FIG. 8 is a diagram explaining a portion D of FIG. 6;

FIG. 9 is a block diagram explaining a semiconductor device according to at least one example embodiment of the present inventive concepts;

FIG. 10 is a timing diagram of the semiconductor device of FIG. 9;

FIG. 11 is a block diagram explaining an electronic system including a semiconductor device according to at least one example embodiment of the present inventive concepts;

FIG. 12 is a diagram explaining a portion E of FIG. 11; and

FIGS. 13 to 15 are views of exemplary semiconductor systems to which a semiconductor device according to at least one example embodiment of the present inventive concepts can be applied.

### DETAILED DESCRIPTION OF EXAMPLE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

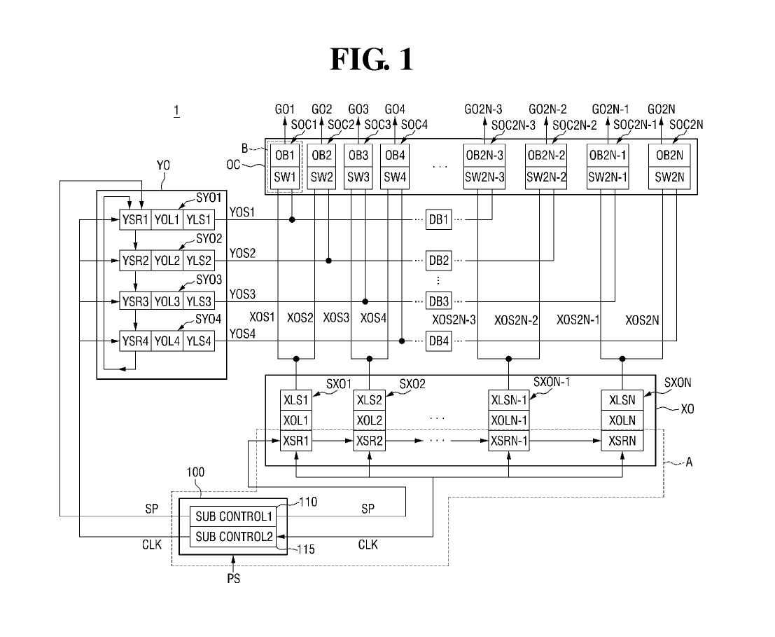

Hereinafter, referring to FIGS. 1 to 8, a semiconductor device according to at least one example embodiment of the present inventive concepts will be described.

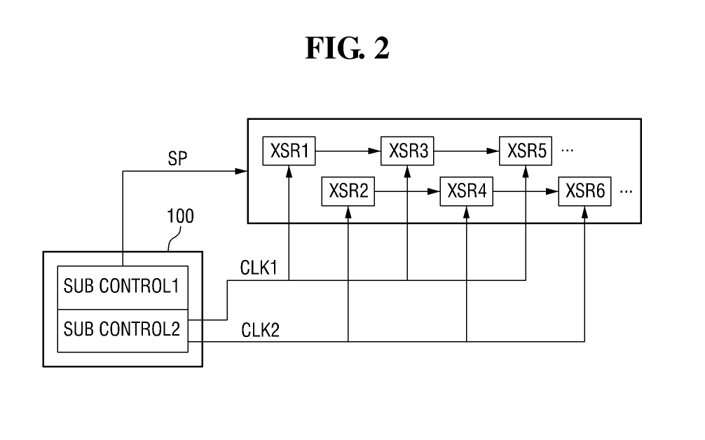

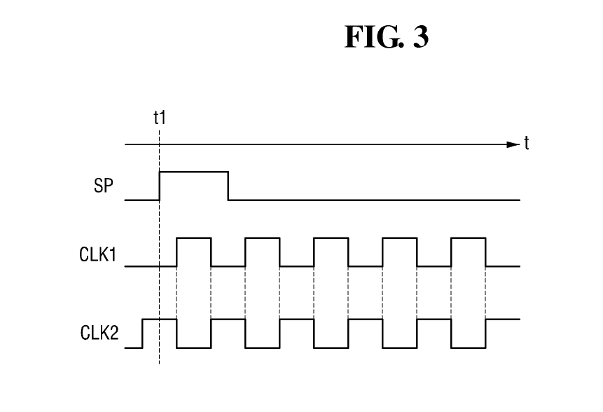

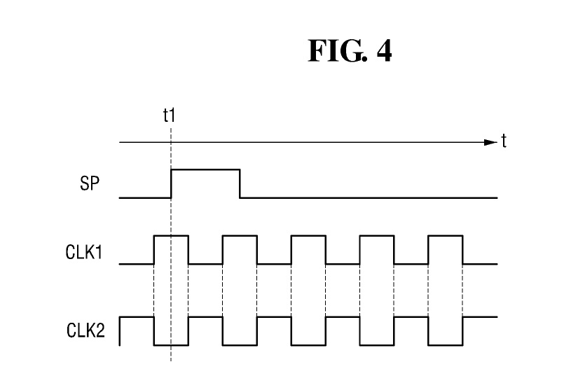

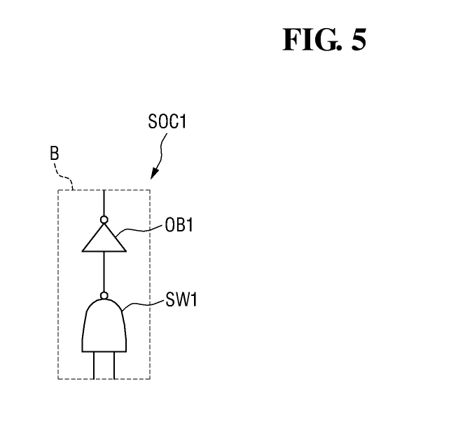

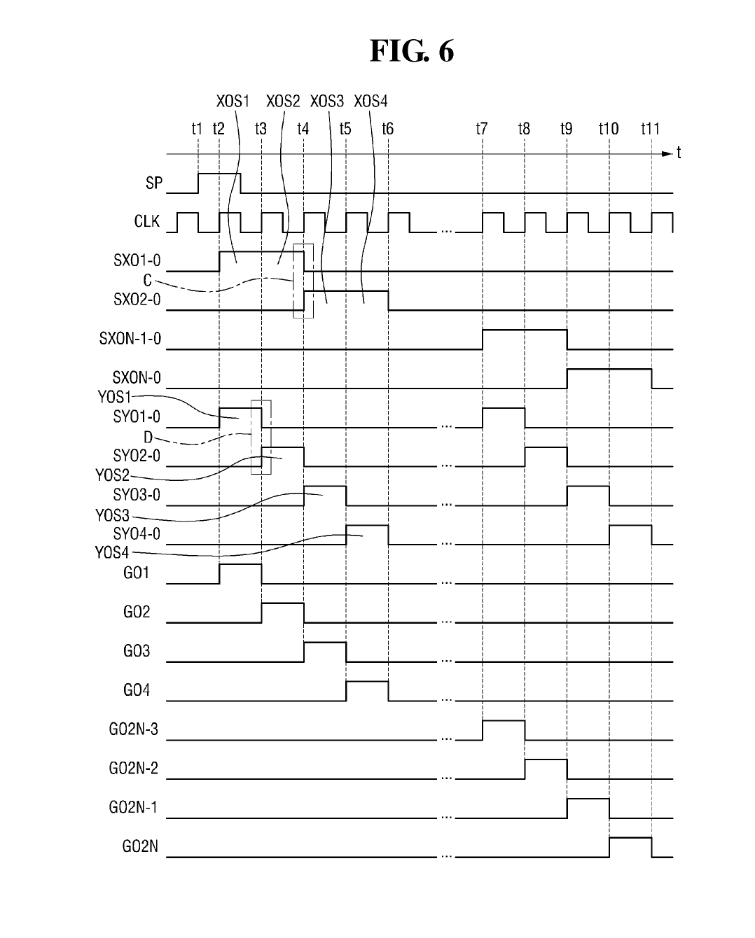

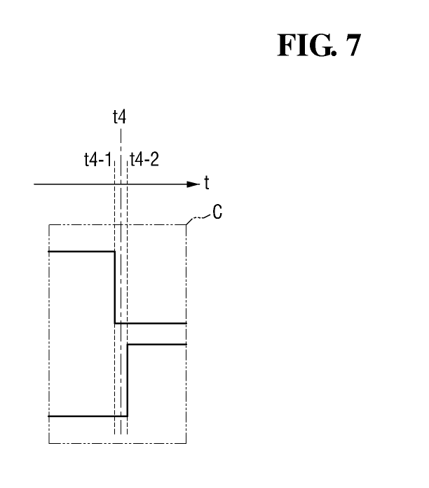

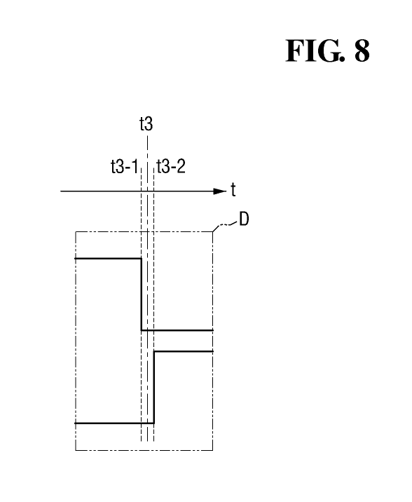

FIG. 1 is a block diagram explaining a semiconductor device according to at least one example embodiment of the present inventive concepts. FIG. 2 is a block diagram explaining another example of a portion A of FIG. 1, and FIGS. 3 and 4 are timing diagrams explaining FIG. 2. FIG. 5 is a diagram explaining a portion B of FIG. 1, and FIG. 6 is a timing diagram explaining the semiconductor device of FIG. 1. FIG. 7 is a diagram explaining a portion C of FIG. 6, and FIG. 8 is a diagram explaining a portion D of FIG. 6.

First, referring to FIG. 1, a semiconductor device 1 according to at least one example embodiment of the present inventive concepts may include a controller 100, an X-axis driver XO, a Y-axis driver YO, an output controller OC, and a delay prevention buffer DB.

First, the controller 100 may generate a control signal based on a specific signal PS that is provided from an outside. Here, the control signal may include a start pulse signal SP and a clock signal CLK, and the specific signal PS may include information related to the start pulse signal SP and the clock signal CLK. Further, the outside that provides the specific signal PS may include, for example, an electronic device or a person, but is not limited thereto.

The controller 100 may include first and second sub-controllers 110 and 115.

Specifically, the first sub-controller 110 may provide the start pulse signal SP to the X-axis driver XO and the Y-axis driver YO. Further, the second sub-controller 115 may provide the clock signal CLK to the X-axis driver XO and the Y-axis driver YO. Here, it is illustrated that one second sub-controller 115 controls the X-axis driver XO and the Y-axis driver YO, but is not limited thereto. For example, the second sub-controller 115 may be divided into a portion that controls the X-axis driver XO and a portion that controls the Y-axis driver YO, and thus may provide separate clock signals to the X-axis driver XO and the Y-axis driver YO.

FIG. 1 illustrates that the first and second sub-controllers 110 and 115 provide the start pulse signal SP and the clock signal CLK to a first sub X-axis driver SXO1 and a second sub Y-axis driver SYO1, but are not limited thereto. That is, the first and second sub-controllers 110 and 115 may provide the start pulse signal SP and the clock signal CLK to the N-th sub X-axis driver SXON (where, N is a natural number that is equal to or larger than 2) and a fourth sub Y-axis driver SYO4. Here, information on where to firstly provide the start pulse signal SP and the clock signal CLK may be included in the specific signal PS.

The X-axis driver XO may receive the start pulse signal SP and the clock signal LCK and generate an X-axis output signal.

Specifically, the X-axis driver XO may include first to N-th sub X-axis drivers SXO1 to SXON. Further, each of the first to N-th sub X-axis drivers SXO1 to SXON may generate at least two sub X-axis output signals. FIG. 1 illustrates that each of the first to N-th sub X-axis drivers SXO1 to SXON generates two sub X-axis output signals, but is not limited thereto. Further, the X-axis output signal as described above includes all the first to 2N-th sub X-axis output signals XOS1 to XOS2N.

Each of the first to N-th sub X-axis drivers SXO1 to SXON may provide two different sub X-axis output signals to any two sub-output controllers. For example, the first sub X-axis driver SXO1 may provide the first and second sub X-axis output signals XOS1 and XOS2 to the first and second sub-output controllers SOC1 and SOC2, and the second sub-axis driver SXO2 may provide the third and fourth sub X-axis output signals XOS3 and XOS4 to the third and fourth sub-output controllers SOC3 and SOC4. Further, the first sub X-axis driver SXO1 may provide the first and second sub X-axis output signals XOS1 and XOS2 to the first and third sub-output controllers SOC1 and SOC3, and the second sub-axis driver SXO2 may provide the third and fourth sub X-axis output signals XOS3 and XOS4 to the second and fourth sub-output controllers SOC2 and SOC4. That is, FIG. 1 illustrates that the first sub X-axis driver SXO1 may provide the first and second sub X-axis output signals XOS1 and XOS2 to the first and second sub-output controllers SOC1 and SOC2, but is not limited thereto. Depending on various conditions and environments, the first and second sub X-axis output signals XOC1 and XOC2 may be provided to other sub-output controllers. Of course, other sub X-axis drivers, except for the first sub X-axis driver SXO1, may operate in the same manner.

Each of the first to N-th sub X-axis drivers SXO1 to SXON may include an X-axis shift register XSR, an X-axis output logic XOL, and an X-axis level shifter XLS. Since the first to N-th sub X-axis drivers SXO1 to SXON have the same structure, only the first sub X-axis driver SXO1 will be described as an example.

Specifically, the first sub X-axis driver SXO1 may include a first X-axis shift register XSR1, a first X-axis output login XOL1, and a first X-axis level shifter XLS1.

The first X-axis shift register XSR1 may shift bit streams that determine the first to 2N-th sub X-axis output signals XOS1 to XOS2N to the second X-axis shift register XSR2 on the basis of the start pulse signal SP and the clock signal CLK. That is, the first X-axis shifter register XSR1 serves to sequentially process the bit streams together with other X-axis shift registers.

The first X-axis shift register XSR1 may be, for example, a linear register.

Here, referring to FIG. 2, another example of the X-axis shift register XSR is illustrated.

Specifically, the X-axis shift register XSR may receive one or more clock signals (e.g., first and second clock signals CLK1 and CLK2), and may perform separate driving or alternate driving of the even/odd shift registers.

As can be seen from FIG. 2, among the X-axis shift registers XSR, the odd-numbered X-axis shift registers (e.g., the first, third, fifth, and seventh X-axis shifter registers XSR1, XSR3, XSR5, and XSR7) may receive the first clock signal CLK1. Further, the even-numbered X-axis shift registers (e.g., the second, fourth, sixth, and eighth X-axis shifter registers XSR2, XSR4, XSR6, and XSR8) may receive the second clock signal CLK2. Here, the first and second clock signals CLK1 and CLK2 may have phases that are opposite to each other.

Referring to FIG. 3, it is illustrated that the start pulse signal SP is changed to a high state at time t1. Accordingly, it can be known that one of the first and second clock signals CLK1 and CLK2, which is first changed from a low state to a high state after the time t1, is the first clock signal CLK1, and the X-axis shift registers alternately operate in the order of 1-2-3-4 (i.e., in the order of odd-even-odd-even numbers). In other words, it can be known that the X-axis shift registers operate in the order of first X-axis shift register—second X-axis shift register—third X-axis shift register—fourth X-axis shifter register.

In contrast, referring to FIG. 4, it can be known that one of the first and second clock signals CLK1 and CLK2, which is first changed from a low state to a high state after the time t1, is the second clock signal CLK2, and the X-axis shift registers alternately operate in the order of 2-1-4-3 (i.e., in the order of even-odd-even-odd numbers). In other words, it can be known that the X-axis shift registers operate in the order of second X-axis shift register—first X-axis shift register—fourth X-axis shift register—third X-axis shifter register.

As described above, the X-axis shifter registers XSR may operate in various manners including sequential driving, alternate driving, and separate driving.

Referring again to FIG. 1, the first X-axis output logic XOL1 may generate an X-axis output logic signal (not illustrated) that determines the states of the first and second sub X-axis output signals XOS1 and XOS2 on the basis of the output of the first X-axis shifter register XSR1.

The first X-axis level shifter XLS1 may generate the first or second sub X-axis output signal XOS1 or XOS2 through boosting of the X-axis output logic signal that is provided from the first X-axis output logic XOL1. That is, a low voltage is used in the first X-axis shifter register XSR1 and the first X-axis output logic XOL1, and the first X-axis level shifter XLS1 serves to boost the low voltage to the high voltage for the output driving.

Further, the first X-axis level shifter XLS1 may sequentially provide the first and second sub X-axis output signals XOS1 and XOS2 to two sub-output controllers (e.g., first and second sub-output controllers SOC1 and SOC2) on the basis of the start pulse signal SP and the clock signal CLK.

The Y-axis driver YO may receive the start pulse signal SP and the clock signal CLK and may generate a Y-axis output signal.

Specifically, the Y-axis driver YO may include first to fourth sub Y-axis drivers SYO1 to SYO4. Further, each of the first to fourth sub Y-axis drivers SYO1 to SYO4 may generate one sub Y-axis output signal.

FIG. 1 illustrates four sub Y-axis drivers, but the number of sub Y-axis drivers is not limited thereto. That is, the Y-axis driver YO may include more than four sub Y-axis drivers. Further, the Y-axis output signal as described above includes all the first to fourth sub Y-axis output signals YOS1 to YOS4.

Each of the first to fourth sub Y-axis drivers SYO1 to SYO4 may provide one sub Y-axis output signal to any N/2 sub-output controllers among the first to 2N-th sub-output controllers SOC1 to SOC2N.

Specifically, for example, if it is assumed that N is 4 and 8 sub-output controllers exist in total, the first sub Y-axis driver SYO1 may provide the first sub Y-axis output signal YOS1 to the first and fifth sub-output controllers SOC1 and SOC5, and the second sub Y-axis driver SYO2 may provide the second sub Y-axis output signal YOS2 to the second and sixth sub-output controllers SOC2 and SOC6. Further, the first sub Y-axis driver SYO1 may provide the first sub Y-axis output signal YOS1 to the second and sixth sub-output controllers SOC2 and SOC6, and the second sub Y-axis driver SYO2 may provide the second sub Y-axis output signal YOS2 to the fourth and eighth sub-output controllers SOC4 and SOC8. FIG. 1 illustrates that the first sub Y-axis driver SYO1 provides the first sub Y-axis output signal YOS1 to the first and second sub-output controllers SOC1 and SOC2, but is not limited thereto. Depending on various conditions and environments, the first sub Y-axis driver SYO1 may provide the first sub Y-axis output signal YOS1 to other sub-output controllers. Of course, other sub Y-axis drivers, except for the first sub Y-axis driver SYO1, may operate in the same manner.

Each of the first to fourth sub Y-axis drivers SYO1 to SYO4 may include a Y-axis shifter register YSR, a Y-axis output logic YOL, and a Y-axis level shifter YLS. Since the first to fourth sub Y-axis drivers SYO1 to SYO4 have the same structure, only the first sub Y-axis driver SYO1 will be described as an example.

Specifically, the first sub Y-axis driver SYO1 may include a first Y-axis shift register YSR1, a first Y-axis output login YOL1, and a first Y-axis level shifter YLS1.

The first Y-axis shift register YSR1 may shift bit streams that determine the first to fourth sub Y-axis output signals YOS1 to YOS4 to the second Y-axis shift register YSR2 on the basis of the start pulse signal SP and the clock signal CLK. That is, the first Y-axis shifter register YSR1 serves to sequentially process the bit streams together with other Y-axis shift registers.

Further the first Y-axis shift register YSR1 may be, for example, a circulating register. Accordingly, the first to fourth Y-axis shift registers YSR1 to YSR4 may be continuously recycled, that is, reused, until all of the first to 2N-th sub-output controllers SOC1 to SOC2N generate driving signals.

Since the Y-axis shift register YSR is a circulating register, the number of sub Y-axis drivers SYO may be smaller than the number of sub X-axis drivers SXO. That is, one of the sub Y-axis drivers may interlock with at least two sub X-axis drivers.

The first Y-axis output logic YOL1 may generate a Y-axis output logic signal (not illustrated) that determines the state of the first sub Y-axis output signal YOS1 on the basis of the output of the first Y-axis shifter register YSR1.

The first Y-axis level shifter YLS1 may generate the first sub Y-axis output signal YOS1 or XOS2 through boosting of the Y-axis output logic signal that is provided from the first Y-axis output logic YOL1. That is, a low voltage is used in the first Y-axis shifter register YSR1 and the first Y-axis output logic YOL1, and the first Y-axis level shifter YLS1 serves to boost the low voltage to the high voltage for the output driving.

Further, the first Y-axis level shifter YLS1 may provide the first sub Y-axis output signal YOS1 to the N/2 sub-output controllers on the basis of the start pulse signal SP and the clock signal CLK.

The output controller may receive X-axis and Y-axis output signals and may generate driving signals GO1 to GO2N.

Specifically, the output controller OC may include first to 2N-th sub-output controllers SOC1 to SOC2N, and each of the sub-output controllers may generate a driving signal GO. Here, the number of sub-output controllers SOC may be equal to the number of sub X-axis output signals of the X-axis drivers XO.

Further, each of the first to 2N-th sub-output controllers SOC1 to SOC2N may include a switch SW and an output buffer OB, and may perform any one of AND, OR, NOR, and NAND operations. Of course, the first to 2N-th sub-output controllers SOC1 to SOC2N may perform other operations in addition to the AND, OR, NOR, and NAND operations, but are not limited thereto. Further, the first to 2N-th sub-output controllers SOC1 to SOC2N have the same structure, and hereinafter, only the first sub-output controller SOC1 will be described as an example.

The first sub-output controller SOC1 includes a first switch SW1 and a first output buffer OB1.

Specifically, the first switch SW1 may receive an X-axis output signal (e.g., first sub X-axis output signal XOS1) and a Y-axis output signal (e.g., first sub Y-axis output signal YOS1). Further, the first output buffer OB1 may receive an output of the first switch SW1 and may generate a first driving signal GO1.

Here, referring to FIG. 5, it is illustrated that the first sub-output controller SOC1 performs an AND operation.

Specifically, the first switch SW1 may be an AND gate, and the first output buffer OB1 may be an inverter. Of course, another inverter may be positioned between the first switch SW1 (i.e., an output terminal of the AND gate) and the first output buffer OB1 (i.e., inverter). As a result, the first sub-output controller SOC1 may perform the AND operation.

As described above, the first sub-output controller SOC1 may perform not only an AND operation but also OR, NAND, and NOR operations. FIG. 5 illustrates an example of the first sub-output controller SOC1.

Referring again to FIG. 1, the first to 2N-th driving signals GO1 to GO2N that are generated by the output controller OC, that is, the first to 2N-th sub-output controllers SOC1 to SOC2N, can drive pixel lines that constitute a display panel. This will be described in detail later.

The delay prevention buffers DB1 to DB4 may be arranged between the Y-axis driver YO and the output controller OC to prevent the delay of the Y-axis output signal.

Specifically, if the number of X-axis drivers XO is relatively larger than the number of Y-axis drivers YO, the length of the semiconductor device (e.g., chip) in an X-axis direction may be lengthened, and this may cause the Y-axis output signal, that is, first to fourth sub Y-axis output signals YOS1 to YOS4, to be delayed. To prevent this, the delay prevention buffers DB1 to DB4 may be arranged between the first to fourth sub Y-axis drivers SYO1 to SYO4 and the sub-output controllers (e.g., the (2N-3)-th to 2N-th sub-output controllers SOC2N-3 to SOC2N), which are spaced far apart from the Y-axis driver YO, among the first to 2N-th sub-output controllers SOC1 to SOC2N.

Hereinafter, referring to FIGS. 1 to 6, the timing diagram of the semiconductor device 1 of FIG. 1 will be described.

First, if the start pulse signal SP becomes high at time t1, the clock signal CLK becomes high at time t2. If the clock signal CLK becomes high, an output SXO1-O of the first sub X-axis driver (hereinafter, an output of the sub X-axis driver means a sub X-axis output signal, and an output of the sub Y-axis driver means a sub Y-axis output signal) becomes high. Here, the first sub X-axis driver SXO1 may sequentially output the first and second sub X-axis output signals XOS1 and XOS2, and thus the first X-axis shift register XSR may sequentially receive a high-state bit twice. Accordingly, the output SXO1-O of the first sub X-axis driver becomes high during a period from time t2 to time t4. Further, the output SYO1-O of the first sub Y-axis driver become high at time t2. However, unlike the first sub X-axis driver SXO1, the first sub Y-axis driver SYO1 outputs only the first sub Y-axis output signal YOS1, and thus the first Y-axis shift register YSR1 receives the high-state bit only once. Accordingly, at time t3, the output SYO1-O of the first sub Y-axis driver becomes low, and the output SYO2-O of the second sub Y-axis driver becomes high. This is because the first Y-axis shift register YSR1 receives a low-state bit and the second Y-axis shift register YSR2 receives a high-state bit from the first Y-axis shift register YSR1. As a result, since the output SXO1-O of the first sub X-axis driver (i.e., first sub X-axis output signal) and the output SYO1-O of the first sub Y-axis driver (i.e., first sub Y-axis output signal) simultaneously become high at time t2, the first driving signal GO1 becomes high. Further, since the output SXO1-O of the first sub X-axis driver (i.e., second sub X-axis output signal) and the output SYO1-O of the second sub Y-axis driver (i.e., second sub Y-axis output signal) simultaneously become high at time t3, the second driving signal GO2 becomes high. Of course, since the output SYO1-O of the first sub Y-axis driver (i.e., first sub Y-axis output signal) becomes low at time t3, the first driving signal GO1 becomes low.

Next, at time t4, the output SXO1-O of the first sub X-axis driver becomes low, and the output SXO2-O of the second sub X-axis driver becomes high. This is because the first X-axis shift register XSR1 receives a low-state bit and the second X-axis shift register XSR2 receives a high-state bit from the first X-axis shift register XSR1. Further, since the third Y-axis shift register YSR3 receives a high-state bit from the second Y-axis shift register YSR2, the output SYO3-O of the third sub Y-axis driver becomes high. As a result, since the output SXO2-O of the second sub X-axis driver (i.e., third sub X-axis output signal) and the output SYO3-O of the third sub Y-axis driver (i.e., third sub Y-axis output signal) simultaneously become high at time t4, the third driving signal GO3 becomes high.

Through repetition of the above-described processes, the first to N-th sub-axis drivers SXO1 to SXON sequentially become high at time t2 (e.g., time t4 to time t2), and the first to fourth Y-axis drivers SYO1 to SYO4 sequentially become high at time t1 (e.g., time t3 to time t2). Of course, since the first to fourth Y-axis shift registers SR1 to SR4 are circulating registers, the first to fourth Y-axis drivers SYO1 to SYO4 may be continuously recycled until time t11. That is, until time t11, the first to fourth sub Y-axis output signals YOS1 to YOS4 become high in the order of 1-2-3-4-1-2-3-4.

Further, the first to 2N-th driving signals GO1 to GO2N sequentially become high at time t1 (e.g., time t3 to time t2). That is, when the sub X-axis output signal XOS and the sub Y-axis output signal YOS, which are provided to the sub-output controllers SOC, simultaneously become high, the respective driving signals GO may become high. This is because the respective sub-output controllers SOC are designed to perform AND operation. That is, if the respective sub-output controllers SOC are designed to perform another operation (e.g., OR, NAND, or NOR operation) that is not the AND operation, the first to 2N-th driving signals GO1 to GO2N may have the results that are different from those of FIG. 6.

FIG. 7 is an enlarged view of a portion C in FIG. 6.

Specifically, a falling edge of the output SXO1-O of the first sub X-axis driver and a rising edge of the output SXO2-O of the second sub X-axis driver may not overlap each other. That is, slightly before time t4 (i.e., time t4-1), the output SXO1-O of the first sub X-axis driver (i.e., second sub X-axis output signal) may become low, and slightly after time t4 (i.e., time t4-2), the output SXO2-O of the second sub X-axis driver (i.e., third sub X-axis output signal) may become high. As described above, the outputs of the continuous sub X-axis drivers among the first to N-th sub X-axis drivers SXO1 to SXON may be set so that the falling edge and the rising edge thereof do not overlap each other.

Then, FIG. 8 is an enlarged view of a portion D in FIG. 6.

Specifically, a falling edge of the output SYO1-O of the first sub Y-axis driver and a rising edge of the output SYO2-O of the second sub Y-axis driver may not overlap each other. That is, slightly before time t3 (i.e., time t3-1), the output SYO1-O of the first sub Y-axis driver (i.e., first sub Y-axis output signal) may become low, and slightly after time t3 (i.e., time t3-2), the output SYO2-O of the second sub Y-axis driver (i.e., second sub Y-axis output signal) may become high. As described above, the outputs of the continuous sub Y-axis drivers among the first to fourth sub Y-axis drivers SYO1 to SYO4 may be set so that the falling edge and the rising edge thereof do not overlap each other.

In addition to FIGS. 7 and 8 as described above, the non-overlap setting between signals can also be applied to the first to 2N-th switches SW1 to SW2N and the first and second sub-controllers 110 and 115.

The semiconductor device 1 according to at least one example embodiment of the present inventive concepts has a structure in which the driver is briefly divided into an X-axis driver XO and a Y-axis driver YO and one sub Y-axis driver YO is shared and used by a plurality of X-axis drivers. Further, since the semiconductor device 1 is configured so that the number of driving signals GO is increased in proportion to the number of X-axis output signals of the sub X-axis driver SXO of the X-axis driver XO, the area of the driver that occupies most of the area of the semiconductor device 1 (e.g., gat driving circuit or chip) can be decreased to secure price competitiveness.

Specifically, if it is assumed that 100 driving signals are required in total, it is enough if the semiconductor device 1 according to at least one example embodiment of the present inventive concepts includes, for example, four sub Y-axis drivers and 50 sub X-axis drivers, but does not require 100 drivers, to remarkably decrease the area of the drivers.

In addition, since the area that is additionally secured according to the decrease of the area of the drivers can be used as a space for improving the circuit performance, the self-performance of the semiconductor device 1 can be improved.

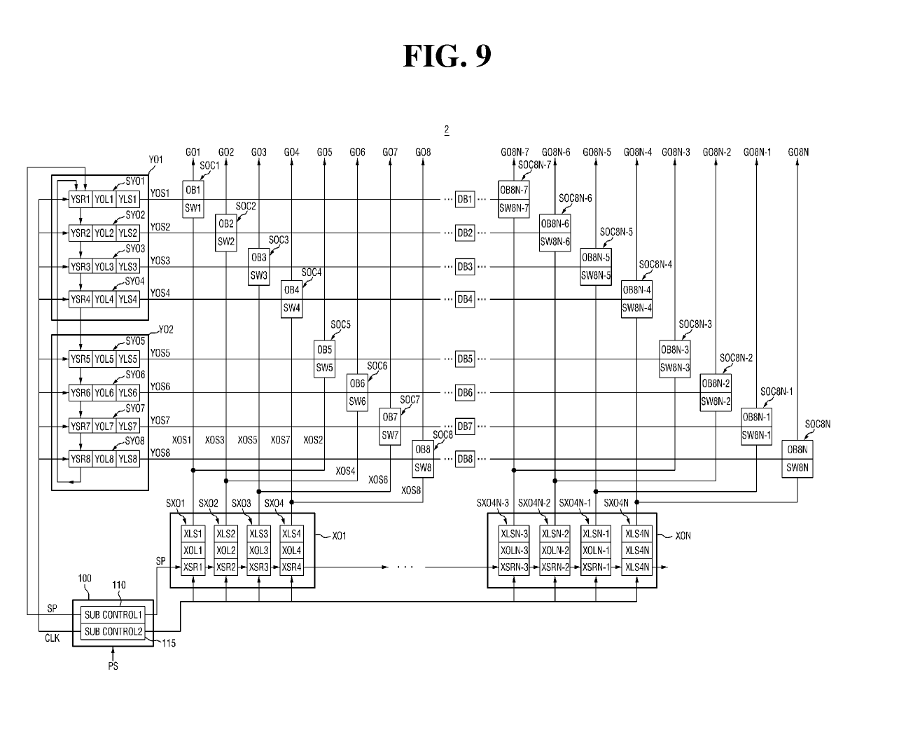

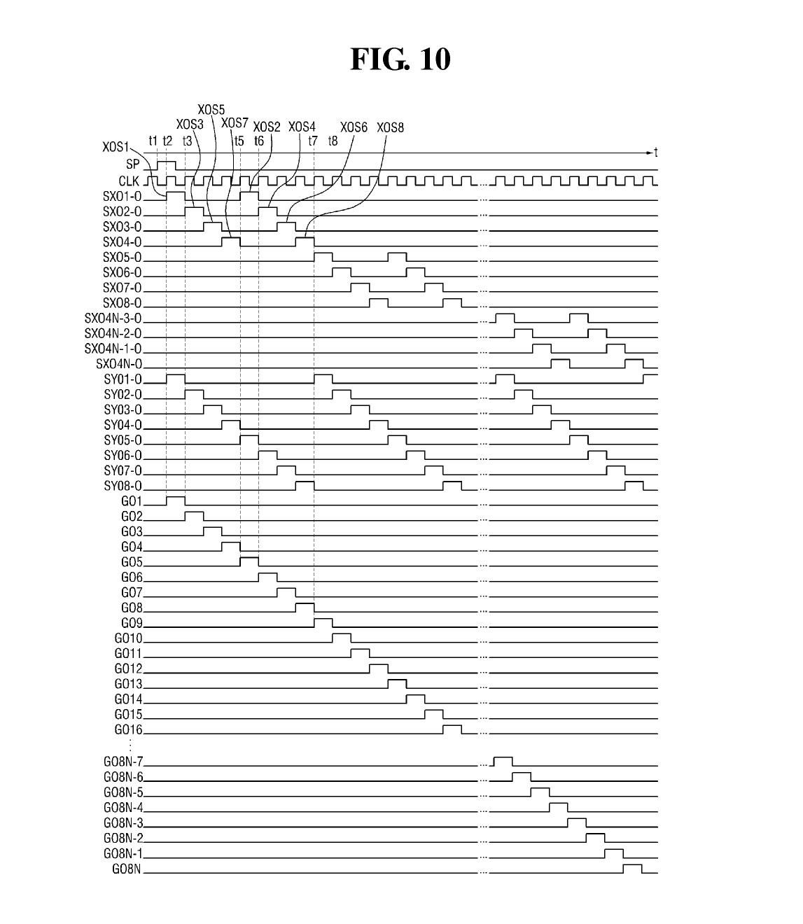

Hereinafter, referring to FIGS. 9 and 10, a semiconductor device according to at least one example embodiment of the present inventive concepts will be described. The explanation will be made around different points between this embodiment and the above-described embodiment, and explanation of the duplicate contents will be omitted.

FIG. 9 is a block diagram explaining a semiconductor device according to at least one example embodiment of the present inventive concepts, and FIG. 10 is a timing diagram of the semiconductor device of FIG. 9.

Referring to FIG. 9, a semiconductor device 2 according to at least one example embodiment of the present inventive concepts may include a controller 100, first to N-th X-axis drivers XO1 to XON, first and second Y-axis drivers YO1 and YO2, an output controller OC, and a delay prevention buffer DB.

First, the controller 100 may include first and second sub-controllers 110 and 115.

Specifically, the first sub-controller 110 may provide the start pulse signal SP to the first X-axis driver XO1 and the first Y-axis driver YO1. Further, the second sub-controller 115 may provide the clock signal CLK to the first X-axis driver XO1 and the first Y-axis driver YO1.

FIG. 9 illustrates that the first and second sub-controllers 110 and 115 provide the start pulse signal SP and the clock signal CLK to the first X-axis driver XO1 and the first Y-axis driver YO1, but are not limited thereto. That is, the first and second sub-controllers 110 and 115 may provide the start pulse signal SP and the clock signal CLK to the N-th X-axis driver XON (where, N is a natural number that is equal to or larger than 2) and the second Y-axis driver YO2.

The first to N-th X-axis drivers XO1 to XON may receive the start pulse signal SP and the clock signal LCK and may generate an X-axis output signal. Here, the first to N-th X-axis drivers XO1 to XON are the same except for the point that the first X-axis driver XO1 receives the start pulse signal SP, and thus the first X-axis driver XO1 will be described as an example.

Specifically, the first X-axis driver XO1 may include first to fourth sub X-axis drivers SXO1 to SXO4. Further, each of the first to N-th sub X-axis drivers SXO1 to SXO4 may generate at least two sub X-axis output signals. FIG. 9 illustrates that each of the first to fourth sub X-axis drivers SXO1 to SXO4 generates two sub X-axis output signals, but is not limited thereto. Further, it is illustrated that the first X-axis driver XO1 includes four sub X-axis drivers, but is not limited thereto. In addition, the X-axis output signal as described above includes all the first to 8N-th sub X-axis output signals XOS1 to XOS8N.

Each of the first to fourth sub X-axis drivers SXO1 to SXO4 may provide two different sub X-axis output signals to any two sub-output controllers. For example, the first sub X-axis driver SXO1 may provide the first and second sub X-axis output signals XOS1 and XOS2 to the first and second sub-output controllers SOC1 and SOC2, and the second sub-axis driver SXO2 may provide the third and fourth sub X-axis output signals XOS3 and XOS4 to the third and fourth sub-output controllers SOC3 and SOC4. That is, FIG. 9 illustrates that the first sub X-axis driver SXO1 may provide the first and second sub X-axis output signals XOS1 and XOS2 to the first and second sub-output controllers SOC1 and SOC2, but is not limited thereto. Depending on various conditions and environments, the first and second sub X-axis output signals XOC1 and XOC2 may be provided to other sub-output controllers. Of course, other sub X-axis drivers, except for the first sub X-axis driver SXO1, may operate in the same manner.

Each of the first to N-th sub X-axis drivers SXO1 to SXON may include an X-axis shift register (e.g., linear register). Accordingly, the second to N-th sub X-axis drivers SXO2 to SXON sequentially operate as the first sub X-axis driver SXO1 as described above, and thus the explanation thereof will be omitted.

Further, each of the first to N-th sub X-axis drivers SXO1 to SXON may include an X-axis output logic and an X-axis level shifter, and the detailed explanation thereof will be omitted.

The first and second Y-axis drivers YO1 and YO2 may receive the start pulse signal SP and the clock signal CLK and may generate a Y-axis output signal.

First, the first Y-axis driver YO1 may include first to fourth sub Y-axis drivers SYO1 to SYO4, and the second Y-axis driver YO2 may include fifth to eighth sub Y-axis drivers SYO5 to SYO8. Further, each of the first to eighth sub Y-axis drivers SYO1 to SYO8 may generate one sub Y-axis output signal.

FIG. 9 illustrates that each of the first and second Y-axis drivers YO1 and YO2 includes four sub Y-axis drivers, but is not limited thereto. That is, each of the first and second Y-axis drivers YO1 and YO2 may include more than four sub Y-axis drivers. However, the number of sub Y-axis drivers in the first and second Y-axis drivers YO1 and YO2 is equal to a half of the number of sub X-axis output signals of the first X-axis driver XO1. This is because the first and second Y-axis drivers YO1 and YO2 bear a half of the first to eighth sub X-axis output signals XOS1 to XOS8 of the first X-axis driver XO1, respectively. More specifically, any one of two sub X-axis output signals that are generated from each of the sub X-axis drivers SXO1 to SXO4 interlocks with the sub Y-axis output signal of the sub Y-axis driver (i.e., one of the first to fourth sub Y-axis drivers SYO1 to SYO4) of the first Y-axis driver YO1, and the other thereof interlocks with the sub Y-axis output signal of the sub Y-axis driver (i.e., one of the fifth to eighth sub Y-axis drivers SYO5 to SYO8) of the second Y-axis driver YO2. Of course, if the number of output signals of the sub X-axis driver of the first X-axis driver XO1 is 3, one more sub X-axes driver that includes four sub Y-axis drivers is required.

That is, in order to prevent two adjacent driving signals from being turned on due to continuous application of the start pulse signal SP to the first X-axis driver XO1 and the first Y-axis driver YO1, the output of the sub X-axis driver (i.e., two sub X-axis output signal) is separated into two outputs, and one of the outputs interlocks with the first Y-axis driver YO1 while the other thereof interlocks with the second Y-axis driver YP2. Accordingly, malfunction that two adjacent driving signals are all turned on can be prevented.

In addition, the sub Y-axis driver of each of the first and second Y-axis drivers YP1 and YP2 may include a Y-axis shift register (e.g., circulating register). Accordingly, the first to eighth sub Y-axis drivers SYO1 to SYO8 may be continuously recycled until all the first to 2N-th driving signals GO1 to GO2N are output.

Further, each of the first and second Y-axis drivers YO1 and YO2 may include a Y-axis output login and a Y-axis level shifter, and the detailed explanation thereof will be omitted.

As a result, in the case where the first sub X-axis output signal XOS1 of the first sub X-axis driver SXO1 is provided to the first sub-output controller SOC1 and the second sub X-axis output signal XOS2 is provided to the fifth sub-output controller SOC5, the sub Y-axis output signal of any one of the first to fourth sub Y-axis drivers SYO1 to SYO4 (e.g., the first sub Y-axis output signal YOS1 of the first sub Y-axis driver SYO1) may be provided to the first sub-output controller SOC1, and the sub Y-axis output signal of any one of the fifth to eighth sub Y-axis drivers SYO5 to SYO8 (e.g., the fifth sub Y-axis output signal YOS5 of the fifth sub Y-axis driver SYO5) may be provided to the fifth sub-output controller SOC 5.

Further, the total number of sub Y-axis drivers SYO is larger than the number of start pulse signals SP that can be continuously applied. For example, if the number of start pulse signals SP that can be continuously applied is 7, it is preferable that the total number of sub Y-axis drivers SYO becomes 8.

Hereinafter, referring to FIGS. 9 and 10, the timing diagram of the semiconductor device 2 of FIG. 9 will be described.

First, if the start pulse signal SP becomes high at time t1, the clock signal CLK becomes high at time t2. If the clock signal CLK becomes high, the output SXO1-O of the first sub X-axis driver and the output SYO1-O of the first sub Y-axis output driver become high. Here, the first sub X-axis driver SXO1 outputs the first sub X-axis output signal XOS1, and the first sub Y-axis driver SYO1 outputs the first sub Y-axis output signal YOS1. Accordingly, the output first driving signal GO1 becomes high.

If the clock signal CLK becomes high again at time t3, the output SXO2-O of the second sub X-axis driver and the output SYO2-O of the second sub Y-axis driver become high. Here, the second sub X-axis driver SXO2 outputs the third sub X-axis output signal XOS3, and the second sub Y-axis driver SYO2 outputs the second sub Y-axis output signal YOS2. Accordingly, the second riving signal GO2 becomes high.

As described above, the first, third, fifth, and seventh sub X-axis output signals XOS1, XOS3, XOS5, and XOS7 of the first to fourth sub X-axis drivers SXO1 to SXO4 may be sequentially output, and the first to fourth sub Y-axis output signals YOS1 to YOS4 of the first to fourth sub Y-axis drivers SYO1 to SYO4 may be sequentially output.

Thereafter, at time t5, as the output SXO1-O of the first sub X-axis driver becomes high again, the second sub X-axis output signal XOS2 is output. In contrast, as the output SYO2-O of the second sub Y-axis driver, other than the first sub Y-axis driver, becomes high, the fifth sub Y-axis output signal YOS5 is output. Accordingly, the output fifth driving signal GO5 becomes high.

Further, at time t6, the output SXO2 of the second sub X-axis driver and the output SYO6 of the sixth sub Y-axis driver become high. Here, the second sub X-axis driver SXO2 outputs the fourth sub X-axis output signal XOS4, and the sixth sub Y-axis driver SYO6 outputs the sixth sub Y-axis output signal YOS6. Accordingly, the output sixth driving signal GO6 becomes high.

As described above, the second, fourth, sixth, and eighth sub X-axis output signals XOS2, XOS4, XOS6, and XOS8 of the first to fourth sub X-axis drivers SXO1 to SXO4 may be sequentially output, and the fifth to eighth sub Y-axis output signals YOS5 to YOS8 of the fifth to eighth sub Y-axis drivers SYO5 to SYO8 may be sequentially output.

Further, from time t7, the fifth to eighth sub X-axis drivers (i.e., the sub X-axis drivers of the second X-axis driver XO2) operate in the same manner as the first to fourth sub X-axis drivers, and the first to eighth sub Y-axis drivers SYO1 to YO8 operate as described above.

That is, the sub X-axis drivers of the second to N-th X-axis drivers XO2 to XON sequentially operate in the same manner as the first to fourth sub X-axis drivers SXO1 to SXO4 as described above, and the first to eighth sub Y-axis drivers SYO1 to SYL8 are continuously recycled until the 8N-th driving signal GO8N is output in high state.

According to the semiconductor device 2 according to at least one example embodiment of the present inventive concepts, the outputs of the sub X-axis drivers (i.e., two sub X-axis output signals) are separated, and one of them interlocks with the first Y-axis driver YO1 while the other thereof interlocks with the second Y-axis driver YO2. Accordingly, malfunction that two adjacent driving signals are all turned on can be prevented. That is, the semiconductor device 2 has the sub Y-axis drivers, the number of which is larger than the number of start pulse signals SP that are continuously applied, and thus even if the start pulse signals SP are continuously applied, the malfunction can be prevented from occurring to heighten reliability.

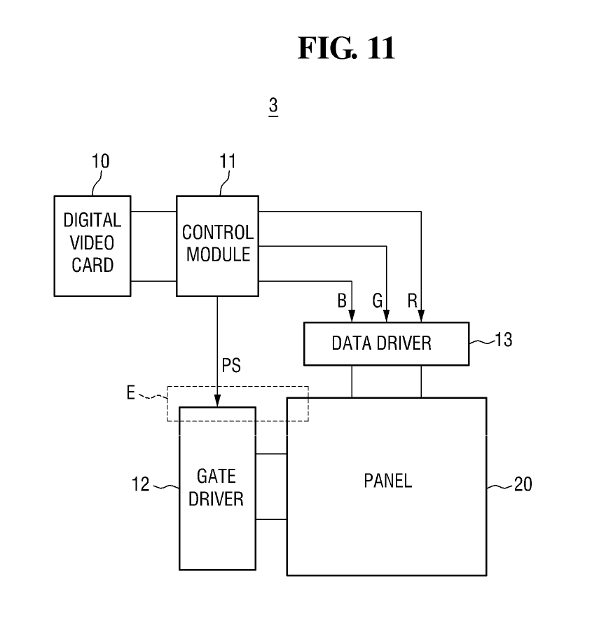

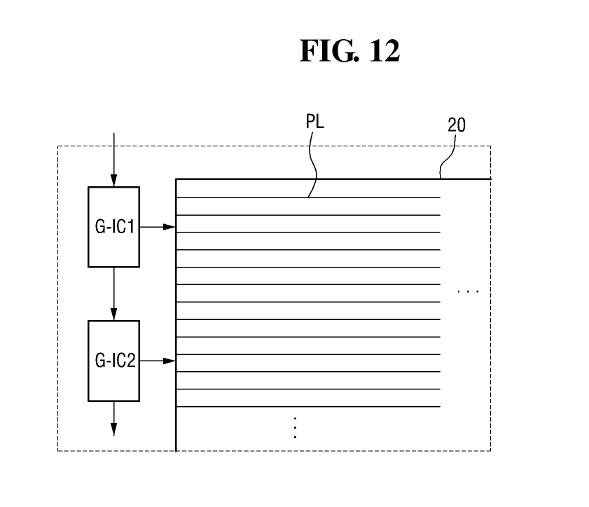

Hereinafter, referring to FIGS. 11 and 12, an electronic system that includes a semiconductor device according to at least one example embodiment of the present inventive concepts will be described. Here, the electronic system may include, for example, a liquid crystal display, but is not limited thereto.

FIG. 11 is a block diagram explaining an electronic system including a semiconductor device according to at least one example embodiment of the present inventive concepts, and FIG. 12 is a diagram explaining a portion E of FIG. 11.

Referring to FIG. 11, an electronic system 3 includes a digital video card 10, a control module 11, a gate driver 12, a data driver 13, and a panel 20.

Specifically, the digital video card 10 may convert an analog video signal into a digital video signal. Further, the digital video card 10 may provide the digital video signal to the control module 11.

The control module 11 may receive the digital video signal from the digital video card 10. Further, the control module 11 may control the provided digital video signal, and may provide a specific signal PS to the gate driver 12.

The gate driver 12 may turn on/off a TFT (Thin Film Transistor) that is a switching element of the panel 20 on the basis of the specific signal PS provided from the control module 11.

The data driver 13 may receive the controlled data signal from the control module 11, and may apply a video signal to a pixel region of the panel 20.

That is, the electronic system 3 that includes the above-described constituent elements first transmits the digital video signal from the digital video card 10 to the control module 11. The control module 11 synchronizes the provided digital video signal, adjusts time control so as to supply the digital video signal to a data bus line of the panel 20, and then transfers the digital video signal to the data driver 13. Further, the control module 11 turns on/off the TFT that is a switching element so as to transfer the video signal that is transmitted through the data bus line to the pixel region in order to display the digital video signal on the panel 20. That is, the control module 11 adjusts the specific signal PS for driving the TFT, and transfers the adjusted specific signal PS to the gate driver 12. Thereafter, the date driver 13 sets addresses on a plurality of date bus lines formed on the liquid crystal panel 20 on the basis of the signal transferred from the control module 11, analog-converts and sequentially transmits the signal on the panel 20.

Further, the gate driver 12 may turn on/off the switching elements by sequentially applying the driving signals to the plurality of gate bus lines formed on the panel 20 to make the video signal transferred from the data bus lines transferred to the respective pixel regions.

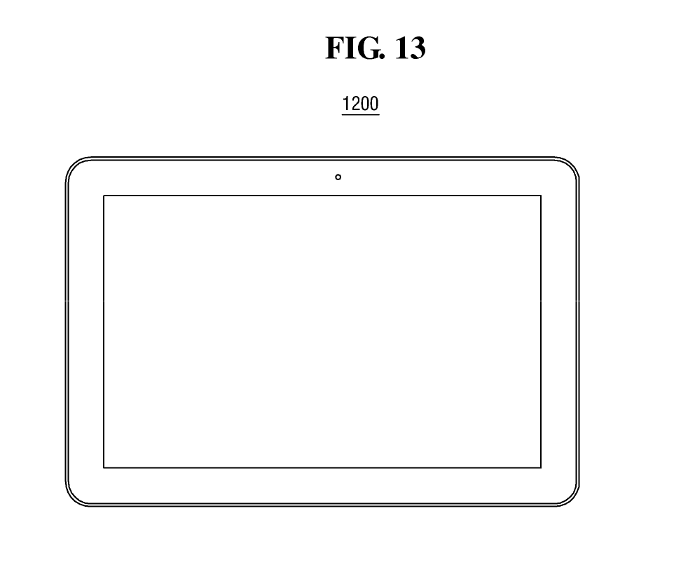

Here, referring to FIG. 13, a portion E of FIG. 12 will be described in more detail.

Referring to FIG. 13, the gate driver 12 may include a plurality of gate driving circuits G-IC1, G-IC2, and the like, and the panel 20 may include a plurality of pixels. Further, the respective pixels may include a plurality of pixel lines PL, that is, gate bus lines.

Accordingly, if the specific signal PS that is provided from the control module 11 is applied to the first gate driving circuit G-IC1, the plurality of gate driving circuits sequentially apply driving signals from the first gate driving circuit G-IC1 to the plurality of pixel lines PL to turn on/off the switching elements. Here, the respective gate driving circuits (e.g., first and second gate driving circuits G-IC1 and B-IC2) may include the semiconductor devices 1 and 2 according to at least one example embodiment of the present inventive concepts.

Hereinafter, referring to FIGS. 13 to 15, exemplary semiconductor systems to which the semiconductor device according to at least one example embodiment of the present inventive concepts can be applied.

FIGS. 13 to 15 are views of exemplary semiconductor systems to which the semiconductor device according to at least one example embodiment of the present inventive concepts can be applied.

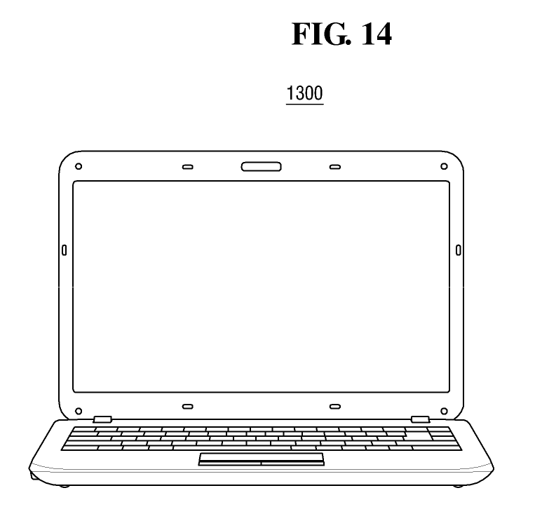

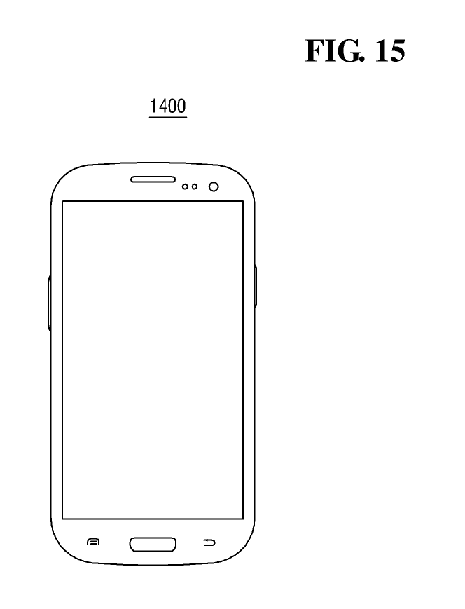

FIG. 13 illustrates a tablet PC 1200, FIG. 14 illustrates a notebook computer 1300, and FIG. 15 illustrates a smart phone 1400. At least one of the semiconductor devices 1 and 2 according to at least one example embodiment of the present inventive concepts may be used in the tablet PC 1200, the notebook computer 1300, or the smart phone 1400.

Further, it is apparent to those of skilled in the art that the semiconductor device according to at least one example embodiment of the present inventive concepts can be applied even to other integrated circuit devices that have not been exemplified. That is, although the tablet PC 1200, the notebook computer 1300, and the smart phone 1400 have been indicated as examples of the semiconductor system according to this embodiment, the examples of the semiconductor system according to this embodiment are not limited thereto. In at least one example embodiment of the present inventive concepts, the semiconductor system may be implemented as a computer, UMPC (Ultra Mobile PC), workstation, net-book, PDA (Personal Digital Assistant), portable computer, wireless phone, mobile phone, e-book, PMP (Portable Multimedia Player), portable game machine, navigation device, black box, digital camera, 3D television set, digital audio recorder, digital audio player, digital picture recorder, digital picture player, digital video recorder, or digital video player.

Although example embodiments of the present inventive concepts have been described for illustrative purposes, those skilled in the art will appreciate that various modifications, additions and substitutions are possible, without departing from the scope and spirit of the inventive concepts as disclosed in the accompanying claims.

What is claimed is:

1. A semiconductor device comprising:
a controller configured to generate a control signal;
an X-axis driver configured to receive the control signal and generating an X-axis output signal that includes first to fourth sub X-axis output signals, the X-axis driver including first and second sub X-axis drivers that are different from each other;
a Y-axis driver configured to receive the control signal and generating a Y-axis output signal that includes first and second sub Y-axis output signals, the Y-axis driver including first and second sub Y-axis drivers that are different from each other; and
an output controller configured to receive the X-axis and Y-axis output signals and generating driving signals, the output controller including first to fourth sub-output controllers that are different from each other,
wherein the first sub X-axis driver is configured to generate and provide the first and second sub X-axis output signals to any two of the first to fourth sub-output controllers, and the second sub X-axis driver is configured to generate and provide the third and fourth sub X-axis output signals to the other two of the first to fourth sub-output controllers, and
wherein the first sub Y-axis driver is configured to generate and provide the first sub Y-axis output signal to any two of the first to fourth sub-output controllers, and the second sub Y-axis driver is configured to generate and provide the second sub Y-axis output signal to the other two of the first to fourth sub-output controllers.

2. The semiconductor device of claim 1, wherein the control signal includes a start pulse signal and a clock signal.

3. The semiconductor device of claim 2, wherein the controller comprises:
a first sub-controller configured to provide the start pulse signal to the X-axis driver and the Y-axis driver; and
a second sub-controller configured to provide the clock signal to the X-axis driver and the Y-axis driver.

4. The semiconductor device of claim 2, wherein the controller is configured to generate the control signal on the basis of a specific signal provided from an outside, and
the specific signal includes information related to the start pulse signal and the clock signal.

5. The semiconductor device of claim 1, wherein the first sub X-axis driver comprises first X-axis shift register and the second sub X-axis drivers comprises second X-axis shift register,
wherein the first X-axis shift register is configured to shift bit streams that determine the X-axis output signals to the second X-axis shift register on the basis of the control signal.

6. The semiconductor device of claim 5, wherein the first sub X-axis driver further comprises:
an X-axis output logic configured to generate an X-axis output logic signal that determines a state of the first and second sub X-axis output signals on the basis of an output of the first X-axis shift register; and
an X-axis level shifter configured to generate the first and second sub X-axis output signals through boosting of a voltage of the X-axis output logic signal.

7. The semiconductor device of claim 6, wherein the X-axis level shifter is configured to sequentially provide the first and second sub X-axis output signals to any two of the first to fourth sub output controllers on the basis of the control signal.

8. The semiconductor device of claim 5, wherein the first and second X-axis shift registers are linear registers.

9. The semiconductor device of claim 1, wherein the X-axis driver further includes third and fourth sub X-axis drivers, and
the first to fourth sub X-axis drivers include first to fourth X-axis shifter registers, respectively.

10. The semiconductor device of claim 9, wherein the control signal includes first and second clock signals having phases that are opposite to each other.

11. The semiconductor device of claim 10, wherein the first clock signal is provided to the first and third X-axis shift registers, and
the second clock signal is provided to the second and fourth X-axis shift registers.

12. The semiconductor device of claim 1, wherein the first and second sub Y-axis drivers comprise first and second Y-axis shifter registers, respectively, and
the first Y-axis shift register are configured to shift bit streams that determines the Y-axis output signal to the second Y-axis shift register on the basis of the control signal.

13. The semiconductor device of claim 12, wherein the first sub Y-axis driver comprises:
A Y-axis output logic configured to generate a Y-axis output logic signal that determines a state of the first and second sub Y-axis output signals on the basis of an output of the first Y-axis shift register; and
A Y-axis level shifter configured to generate the first and second sub Y-axis output signals through boosting of a voltage of the Y-axis output logic signal.

14. The semiconductor device of claim 12, wherein the first and second Y-axis shift register are circulating registers.

15. The semiconductor device of claim 1, wherein the first sub-output controller comprises:
a switch configured to receive an X-axis output signal and a Y-axis output signal; and
an output buffer configured to receive an output of the switch and generating a driving signal.

16. The semiconductor device of claim 15, wherein the first sub-output controller performs any one of AND, OR, NOR, and NAND operations.

17. The semiconductor device of claim 1, wherein the first to fourth sub X-axis output signals do not overlap each other, and
the first and second sub Y-axis output signals do not overlap each other.

18. The semiconductor device of claim 1, further comprising a delay prevention buffer arranged between the Y-axis driver and the output controller configured to prevent delay of the Y-axis output signal.

19. A semiconductor device comprising:
a controller configured to generate a control signal;
an X-axis driver configured to receive the control signal and configured to generate an X-axis output signal that includes first to fourth sub X-axis output signals, the X-axis driver including first and second sub X-axis drivers that are different from each other;
a first Y-axis driver configured to receive the control signal and configured to generate a first Y-axis output signal that includes first and second sub Y-axis output signals, the first Y-axis driver including first and second sub Y-axis drivers that are different from each other;
a second Y-axis driver configured to receive the control signal and configured to generate a second Y-axis output signal that includes third and fourth sub Y-axis output signals, the second Y-axis driver including third and fourth sub Y-axis drivers that are different from each other; and
an output controller configured to receive the X-axis and the first and second Y-axis output signals and configured to generate driving signals, the output controller including first to fourth sub-output controllers that are different from each other,
wherein the first sub X-axis driver is configured to generate and provide the first and second sub X-axis output signals to any two of the first to fourth sub-output controllers, and the second sub X-axis driver is configured to generate and provide the third and fourth sub X-axis output signals to the other two of the first to fourth sub-output controllers, and
wherein the first and second sub Y-axis drivers are configured to generate and provide the first and second sub Y-axis output signals to the two sub-output controllers to which the first and third sub X-axis output signals are provided, and the third and fourth sub Y-axis drivers are configured to generate and provide the third and fourth sub Y-axis output signals to the other two sub-output controllers to which the second and fourth sub X-axis output signal is provided.

20. A semiconductor device comprising:
a controller configured to generate a start pulse signal and a clock signal;
a driver configured to receive the start pulse signal and the clock signal and generating output signals; and
an output controller configured to receive the output signals and generating driving signals,
wherein the driver includes a plurality of X-axis drivers and a plurality of Y-axis drivers,
each of the plurality of Y-axis drivers is configured to interlock with at least two of the plurality of X-axis drivers,
each of the plurality of X-axis drivers is configured to generate at least two X-axis output signals, and
the output controller is configured to generate the driving signals on the basis of Y-axis output signals generated by the plurality of Y-axis drivers and X-axis output signals generated by the plurality of X-axis drivers.
